(19) United States
(12) Patent Application Publication
(10) Pub. No.: US 2007/0079749 A1
(43) Pub. Date: Apr. 12, 2007

(54) Method and apparatus for producing spherical silicon single-crystal

(76) Inventors: Kosuke Nagashio, Sagamihara-shi (JP); Kazuhiko Kuribayashi, Sagamihara-shi (JP); Hideki Okamoto, Sagamihara-shi (JP)

Correspondence Address: JACOBSON HOLMAN PLLC, 400 SEVENTH STREET N.W., SUITE 600, WASHINGTON, DC, 20004, US

(21) Appl. No.: 11/543,842

(22) Filed: Oct. 6, 2006

(30) Foreign Application Priority Data
Oct. 6, 2005 (JP) 2005-293807

(51) Int. Cl. C30B 15/00; C30B 21/06; C30B 27/02; C30B 28/10; C30B 30/04

(52) U.S. Cl. 117/13

(57) ABSTRACT

Disclosed is a method for producing a spherical silicon single-crystal, which comprises the steps of heating and melting a silicon material held in a vessel, keeping the molten silicon material at a temperature around its melting point for a given time-period to partly solidify the molten silicon material, and dropping the molten silicon material including a solidified portion, from the vessel into a gas phase. The spherical silicon single-crystal production method of the present invention makes it passable to obtain a spherical silicon single-crystal having a higher degree of crystallinity with enhanced efficiency in a simplified manner.

### BACKGROUND OF THE INVENTION

1. Field of the Invention

The present invention relates to a method and apparatus for producing a spherical silicon single-crystal. More particularly, the present invention relates to a spherical silicon single-crystal production method capable of obtaining a spherical silicon single-crystal having a higher degree of crystallinity with enhanced efficiency at lower cost as compared with a conventional technique, and an apparatus capable of implementing the method.

2. Description of the Related Art

It is about thirty years to the present since a solar cell was regarded as one of key alternatives to oil-based energy generation means, and the adoption of solar-cell technologies was positively started. In the year 2002, a power generation capacity of solar cells actually used in Japan is increased up to about 200,000 kW, which is about 50% of the world total. In this light, it can be said that Japan plays a role in the world as a driving force for the adoption of solar cells. That said, as compared with conventional energy sources, such as oil, the scope of application or an adoption rate of solar cells has not reached a satisfactory level.

With a view to promoting the utilization of a safe primary energy source free from adverse effects on earth's energy balance in Japan, it would be a key factor to accelerate the adoption of solar cells, particularly, to achieve enhanced economical efficiency in current solar cell-related technologies, and technical innovation for next-generation technologies in the technical field of solar cells. In this field, as one alternative to conventional techniques using a polycrystalline wafer, it has already been started to carry out researches on a technique of growing a spherical silicon single-crystal having a diameter of about 1 mm and forming a circuit on a surface of the spherical silicon single-crystal to produce a next-generation solar cell. A spherical silicon single-crystal is used in view of the following advantages: (1) An equipment investment can be scaled down; (2) Silicon scraps, which have otherwise been generated in a silicon cutting process essential to conventional techniques, can be eliminated; and (3) A device having 3-dimensionally arranged silicon single-crystals can be produced by utilizing a spherical shape of the silicon single-crystal.

W. R. McKee, “IEEE Trans. on components, hybrids, and manufacturing technology”, Vol. CHMT-5, 336 (1982), discloses a technique for obtaining a spherical silicon single-crystal with a diameter of about 1 mm as mentioned above. FIG. 6 schematically shows the technique disclosed in this publication. Specifically, in a first process as shown in FIG. 6(a), a carbon susceptor 64 is heated by an RF coil 62 to melt silicon 63 in a crucible. Ar gas 61 is supplied from above the crucible to allow droplets 65 of the molten silicon to be injected from a lower nozzle so as to form a plurality of silicon spheres 66 each having an even particle size. Then, in a second process as shown in FIG. 6(b), the silicon spheres 66 formed in the first process are dropped one-by-one in a heating furnace comprising an RF coil 62 and a carbon susceptor 64, to obtain a plurality of spherical silicon single-crystals 67.

As above, this technique is based on the two-stage process which is undesirable in terms of productivity.

Recently, many venture companies in Japan have tried a new approach to directly growing a spherical single-crystal only through a single-stage process. This approach includes techniques as disclosed, for example, in Japanese Patent Laid-Open Publication Nos. 11-012091, 2000-169279, 2003-306706 and 2002-292265.

All of these conventional techniques are intended to solidify a molten droplet of a semiconductor material, such as silicon, or a metal material, while levitating or dropping the molten material. That is, the molten droplet is solidified based on a so-called “container-less” solidification process. In view of crystal growth, comparing the spherical single-crystal growth technique based on the container-less solidification process with a single-crystal-ingot growth technique based on a conventional Czochralski (CZ) process, while a solid-liquid interface in the latter technique has a positive temperature gradient, a solid-liquid interface in the former technique has a negative temperature gradient because a region of the molten droplet on a front side of the solid-liquid interface is highly supercooled. This difference between the two techniques causes a difference in a control parameter to be used in each of the crystal growing processes. Specifically, in the CZ process, the growth rate can be externally controlled by a pull-up speed of a seed crystal so as to optimize a temperature gradient and a rotation speed of the seed crystal to achieve formation of a single crystal with a smooth solid-liquid interface. In the container-less solidification process, a growth rate has a unique correlation with a degree of supercooling, and therefore the growth rate can be controlled by externally controlling the degree of supercooling. However, in the container-less solidification process, there is no container wall serving as a main heterogeneous nucleation site. Thus, a melt is highly supercooled, and a growth interface becomes unstable due to the negative temperature gradient, which typically results in the dendrite growth. As above, the crystal growth technique based on the container-less solidification process is significantly different from that based on the conventional CZ process. Therefore, CZ process-related techniques previously accumulated by a great number of researchers cannot be diverted to a technique for forming a spherical single-crystal based on the container-less solidification process.

In the container-less solidification process, a great number of dendrites grow in a sample droplet of a semiconductor material, such as silicon, or a metal material, during dropping, to cover a surface of the sample droplet, and then the sample droplet is solidified toward a center thereof based on the great number of dendrites serving as crystal nuclei. Thus, the sample is formed as a polycrystal.

Japanese Patent Laid-Open Publication No. 2002-348194 includes a description that, when a single silicon droplet is levitated by an electromagnetic levitation technique, a seed crystal can be introduced in the silicon droplet from outside to achieve crystallization at any degree of supercooling, specifically, to form a single crystal at a low degree of supercooling. In connection with the technique designed to inject a molten droplet, as disclosed in this publication, researches for preventing polycrystallization due to the dendrite growth have been made. For example, a plate for inducing nucleation is disposed below a nozzle to forcibly facilitate solidification at a low degree of supercooling. However, a technique capable of forcibly inducing nucleation in all of a great number of molten droplets has not been established so far.

[Patent Publication 1] Japanese Patent Laid-Open Publication No. 11-012091

[Patent Publication 2] Japanese Patent Laid-Open Publication No. 2000-169279

[Patent Publication 2] Japanese Patent Laid-Open Publication No. 2003-306706

[Patent Publication 3] Japanese Patent Laid-Open Publication No. 2002-292265

[Patent Publication 4] Japanese Patent Laid-Open Publication No. 2002-348194

[Non-Patent Publication 1] W R. McKee, IEEE Trans. on components, hybrids, and manufacturing technology, Vol. CHMT-5, 336 (1982)

### SUMMARY OF THE INVENTION

In view of the above circumstances, it is an object of the present invention to provide a spherical silicon single-crystal production method and a spherical silicon single-crystal production apparatus, capable of obtaining a spherical silicon single-crystal having a higher degree of crystallinity with enhanced efficiency in a simplified manner.

Through various researches for achieving the above object, the inventors found that that the above object can be achieved by employing a semisolid process, i.e., by dropping or injecting a silicon sample in a solid-liquid coexistent state. Based on this knowledge, the inventors have finally reached the present invention. According the present invention, all of dropped or injected sample droplets include a solid thereinside. This solid serves as a nucleus for crystallization to allow the molten droplet to be solidified at a melting point without supercooling, and formed as a single crystal.

In the case where an impurity is introduced in a silicon droplet from outside to crystallize the droplet, as in the conventional technique, while nucleation occurs at a surface of the impurity, a supercooling of the sample droplet is unavoidable due to the impurity materially different from silicon.

In the present invention, a solid-phase substance materially identical to a sample droplet exists inside the sample droplet. Thus, a single crystal can be grown at a melting point of the sample droplet without supercooling.

Specifically, according to a first aspect of the present invention, there is provided a method for producing a spherical silicon single-crystal, which comprises the steps of heating and melting a silicon material held in a vessel, keeping the molten silicon material at a temperature around its melting point for a given time-period to partly solidify the molten silicon material, and dropping the molten silicon material including a solidified portion, from the vessel into a gas phase.

In the method of the present invention, in the step of heating and melting a silicon material held in a vessel, the silicon material may be heated up to the melting point of silicon of the silicon material or a temperature greater than the melting point, in such a manner as to be fully molted in its entirety.

Then, in the method of the present invention, the fully molten silicon material is solidified at a desired percentage thereof. This is achieved by keeping the molten silicon material at a temperature around the melting point for a given time-period. The time-period for allowing the molten silicon material to be kept at a temperature around the melting point can be adjusted to partly solidify the molten silicon material at any percentage. For example, it is preferable to solidify 30% of the molten silicon material.

Further, in the method of the present invention, in order to drop the molten silicon material including a solidified portion, from the vessel into a gas phase, inert gas, such as Ar gas, may be supplied from above the vessel to allow the molten silicon material to be dropped from a nozzle provided at a lower portion of the vessel, in the form of a sample droplet.

In one embodiment of the present invention, preferably, the method further includes the step of heating the partly-solidified molten silicon material to melt a part of the solidified portion. The solidified portion may be partly molten at a percentage allowing a part of the solidified portion attached onto an inner wall of the vessel to be released therefrom.

In another embodiment of the present invention, preferably, the method further includes the step of stirring the partly-solidified molten silicon material to crush the solidified portion.

In a second aspect of the present invention, there is provided an apparatus for producing a spherical silicon single-crystal, which comprises a vessel for holding a silicon material, heating means for heating and melting the silicon material held in the vessel, stirring means for stirring the molten silicon material, and a nozzle for allowing the molten silicon material in the vessel to be dropped into a gas phase. The apparatus is designed to form a temperature gradient in the molten silicon material in the vessel so as to allow the molten silicon material to be partly solidified.

In the apparatus of the present invention, the temperature gradient may be formed to have a high-temperature region allowing the silicon material to be fully molten, and a low-temperature region allowing the silicon material to start to solidify.

In one embodiment of the present invention, preferably, the vessel includes a crucible having an inner wall at least partly made of boron nitride, and the stirring means includes a rod made of boron nitride.

As above, according to the present invention, a silicon material is partially molten, and then solidified from a center to a surface thereof at a melting point thereof, so as to achieve formation of a single crystal. Further, in a process of producing spherical silicon single-crystals, a spherical silicon single-crystal having excellent crystallinity can be obtained at a higher rate.

In addition, the spherical silicon single-crystal can be obtained through a single-stage process to scale down a production facility or equipment, and reduce a solidification time so as to achieve enhanced productivity.

Other features and advantages of the present invention will be apparent from the accompanying drawings and from the detailed description.

### BRIEF DESCRIPTION OF THE DRAWINGS

FIG. 1 is a schematic block diagram showing a spherical silicon single-crystal production apparatus according to one embodiment of the present invention.

FIG. 2 is a graph showing the concept of adjusting a holding time at a temperature around a melting point to control a percentage of a molten silicon to be solidified.

FIG. 3 is a graph showing respective heating curves (a), (b) employed in Comparative Example and Inventive Example.

FIG. 4 is respective photographs of surfaces (upper side) and respective crystal orientation maps of cross-sections (lower side) in three spherical silicon samples (a) to (c) different in the number of grains.

FIG. 5 is graphs (I), (II) showing evaluation results of each percentage of the three types of spherical silicon samples (a) to (c) in the Comparative Example and the Example of the present invention, respectively.

FIG. 6 is a schematic block diagram showing a conventional spherical silicon single-crystal production apparatus.

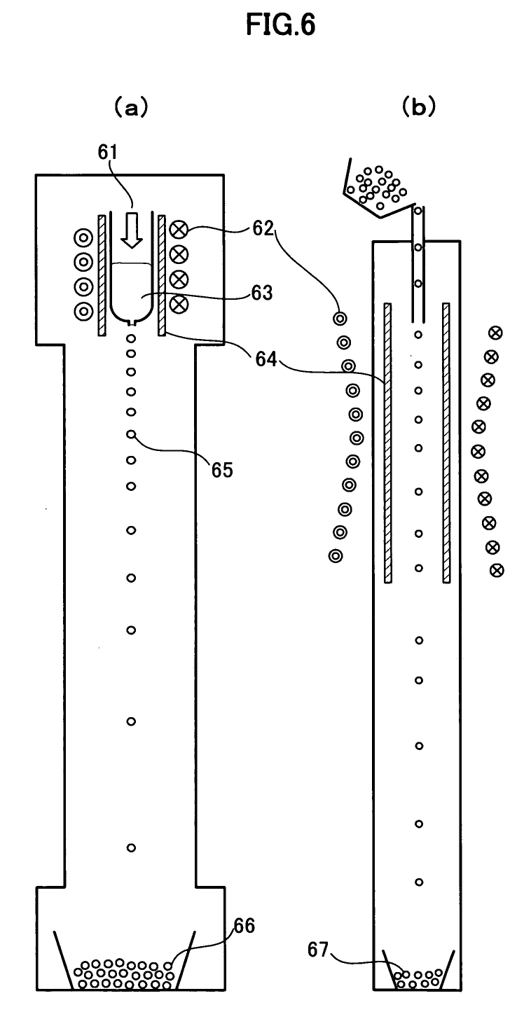

### DETAILED DESCRIPTION OF THE PREFERRED EMBODIMENTS OF THE INVENTION

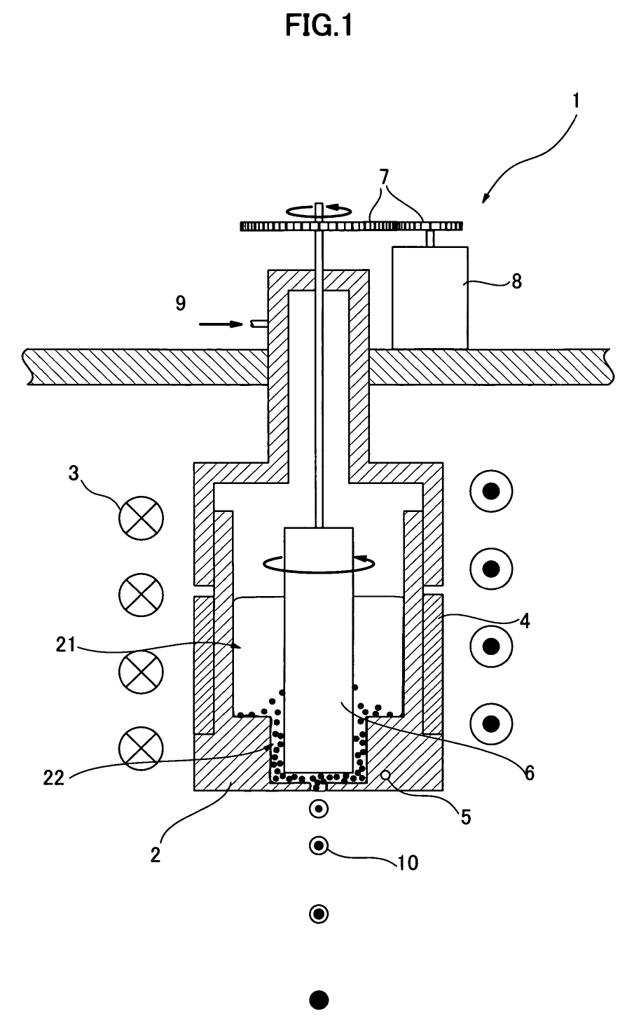

With reference to the drawings, one embodiment of the present invention will now be described. FIG. 1 is a schematic block diagram showing a spherical silicon single-crystal production apparatus 1 according to one embodiment of the present invention.

The apparatus 1 comprises a crucible 2 made of boron nitride and designed to receive a silicon ingot therein. An RF coil 3 is disposed around the boron nitride crucible 2 and designed to be applied with a high-frequency current so as to heat a carbon member 4 attached onto an outer side surface of the boron nitride crucible 2.

In this apparatus according to this embodiment, the RF coil 3 and the carbon member 4 are appropriately arranged to allow a given temperature gradient ranging from a high-temperature region 21 to a low-temperature region 22 to be formed in the molten silicon material.

The apparatus according to this embodiment further includes a rod 6 made of boron nitride and designed to stirring the molten silicon material. The boron nitride rod 6 is connected to a motor 8 through a gear 7. The boron nitride crucible 2 has an upper portion provided with a gas supply port 9, and a lower portion provided with a nozzle for allowing the molten silicon material to be injected therefrom in the form of a sample droplet 10, in response to supplying inert gas, such as Ar gas, from the gas supply port 9 into the boron nitride crucible 2.

In a process of producing a spherical silicon single-crystal using the above apparatus according to this embodiment, the carbon member 4 attached onto the outer side surface of the boron nitride crucible 2 is heated up to the melting point of silicon or a temperature greater than the melting point, so as to heat and fully melt a silicon ingot held in the boron nitride crucible 2.

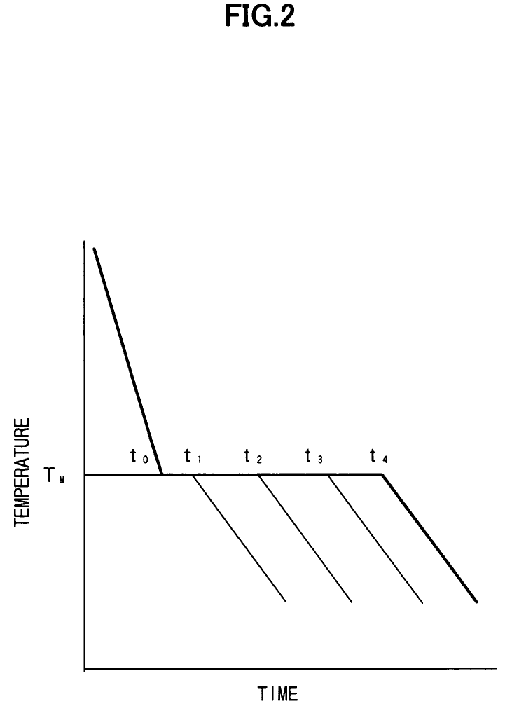

Then, the molten silicon material is kept at a temperature around the melting point for a given time-period in such a manner as to be partly solidified. A part of the molten silicon material to be solidified can be adjusted at any percentage thereof by controlling the time-period for allowing the molten silicon material to be kept at a temperature around the melting point, for example, as shown in FIG. 2. Specifically, in FIG. 2, given that a time-period required for fully solidifying a silicon material molted at a temperature greater than a melting point T_{M} thereof and then kept at the melting point T_{M} is (t₄−t₀), a percentage f of a solidified portion in a state just after the molten silicon material is kept at the melting point T_{M} for a time-period from t0 to t1 is estimated as follows: f=(t1−t₀)/(t₄−t₀). In view of setting the viscosity of the molten droplet in an adequate range, for example, it is preferable to solidify 30% of the molten silicon ingot.

Further, according to need, the partly-solidified silicon material is re-heated to allow a part of the solidified portion attached to an inner wall of the boron nitride crucible 2 to be released from the inner wall.

Then, in order to drop the molten silicon material including a solidified portion, from the boron nitride crucible 2 into a gas phase, inert gas, such as Ar gas, is supplied from the gas supply port 9 provided in the upper portion of the vessel, to inject the molten silicon material from the nozzle provided in the lower portion of the vessel, in the form of a sample droplet. Typically, the nozzle has an inner diameter of about 1 mm.

In the above process using the apparatus according to this embodiment, a nucleation/solidification initially occurs around the inner wall of the boron nitride crucible 2. Thus, it is considered that the solidified portion or solid in the molten silicon material is attached onto the inner wall of the boron nitride crucible 2 instead of dispersedly existing in the molten silicon material in the form of micro-crystals. In this state, the silicon material is re-heated to partly melt the solidified portion so as to create a solid-liquid coexistent state in which ultra-fine solids are dispersed over a liquid phase. This makes it possible to inject the molten silicon material as a sample droplet in the solid-liquid coexistent state, i.e., in a semi-molten/semi-solidified state. In this case, it is considered that a single solid particle serving as a nucleus is included in the injected sample droplet, and therefore the sample droplet is slowly solidified from the inside thereof toward outside without supercooling while allowing the single solid particle to be grown as a spherical single-crystal. This growth process makes it possible to eliminate the need for control of a degree of supercooling in the sample droplet which was an unsolvable technical problem of the conventional techniques.

Further, in the apparatus according this embodiment, the partly-solidified molten silicon material is agitated by the boron nitride rod 6 to crush the solidified portion. While any suitable means other than the mechanical agitation, such as electromagnetic agitation, supersonic vibration or mechanical vibration, may be used for crushing the solidified portion of the molten silicon material, the mechanical agitation is preferable in view of a high disruptive force. While a desirable distance between the boron nitride rod 6 and the inner wall of the boron nitride crucible 2 is varied depending on a shape of the boron nitride rod and a size of the entire apparatus, a minimum value in each of vertical and horizontal distances is preferably set at about 1 mm. Preferably, a rotation speed of the boron nitride rod 6 is set at about 50 to 100 rpm.

### EXAMPLE

It was tried to form a spherical single-crystal of silicon by using a drop tube having a length of 26 m, heating and melting about 1 g of silicon in a crucible (inner diameter: 15 mm, length: 70 mm) located at an uppermost portion of the tube, and injecting the molten silicon from a nozzle of 1 mmφ provided in a lower portion of the crucible.

### Comparative Example

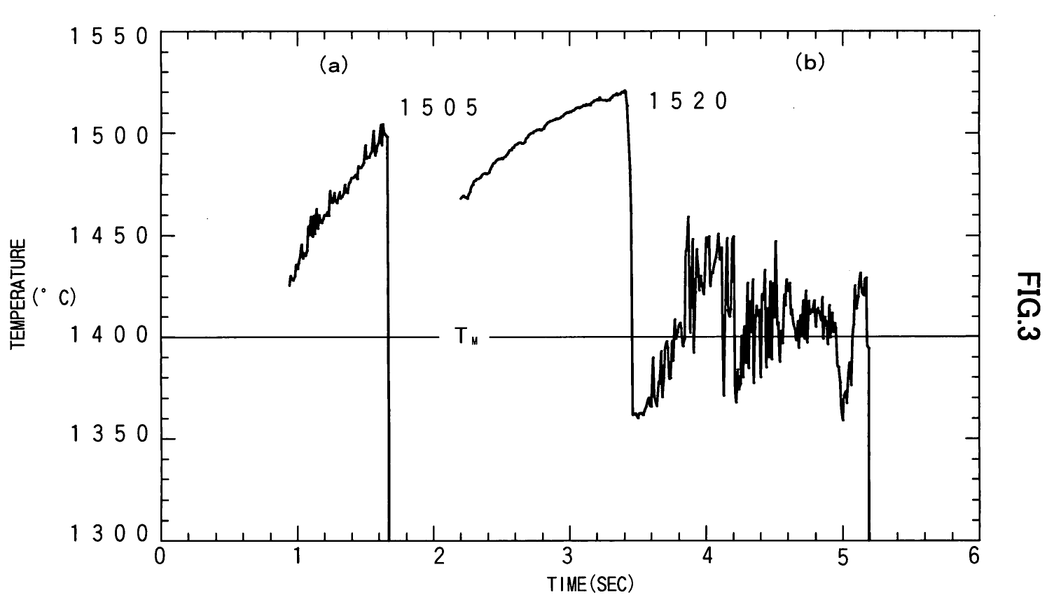

As indicated by a curve (a) in FIG. 3, the silicon was heated and molten up to a temperature (1505° C.) greater than the melting point T_{M} of silicon, and the molten silicon was injected in a superheated state.

### Inventive Example

As indicated by a curve (b) in FIG. 3, the silicon was fully molten in the crucible at a temperature (1520° C.) greater than the melting point T_{M}, and then an output of a heating power supply was reduced to cool the silicon to the melting point T_{M}. Subsequently, the silicon was kept at the melting point T_{M} for a time-period slightly less than two seconds, and then re-heated to melt a part of the silicon which was crystallized around an inner wall of the crucible or the nozzle. Then, the molten droplet was injected.

### Evaluation

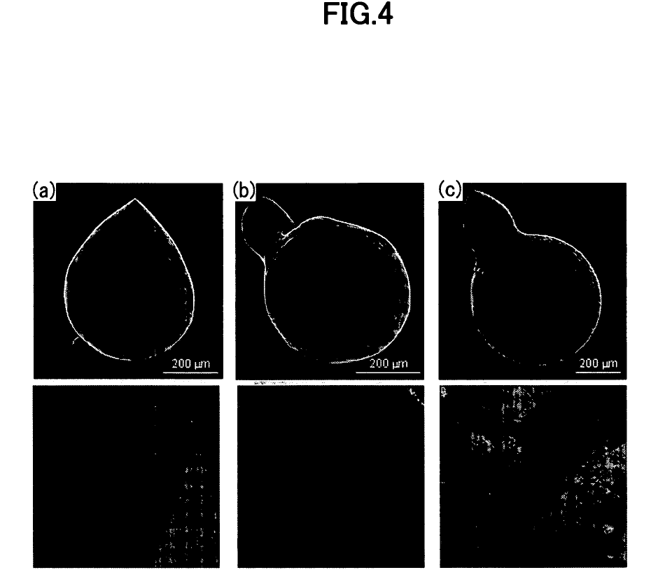

FIG. 4 shows respective photographs of surfaces (upper side) and respective backscatter diffraction crystal orientation maps of cross-sections (lower side) in three spherical silicon samples (a), (b), (c) different in the number of grains. The number of grains in the samples (a), (b), (c) increases in alphabet order. From the results of previous fundamental researches on a solidification structure and a degree of supercooling, it is known that a degree of supercooling before solidification in the samples (a), (b), (c) becomes higher in alphabet order [see, for example, Liu, R. P., Volkmann, T., and Herlach, D. M., “Undercooling and solidification of Si by electromagnetic levitation”, Acta Mater., 49, 439-444 (2001), Jian, J., Nagashio, K. and Kuribayashi, K., “Direct observation of the crystal growth transition in undercooled silicon”, Metall. Mater. Trans. A, 33A, 2947-2853 (2002), and Nagashio, K., Okamoto, H., Kuribayashi, K. and Jinbo, I., “Fragmentation of facet dendrites in solidification of undercooled B-doped Si melt”, Metall. Mater. Trans. A. (36A, 3407-3413 (2005))]. While the sample (a) is solidified at the melting point almost without supercooling, a degree of supercooling in the sample (b) is about 100 K, and a degree of supercooling in the sample (c) is greater than 200 K.

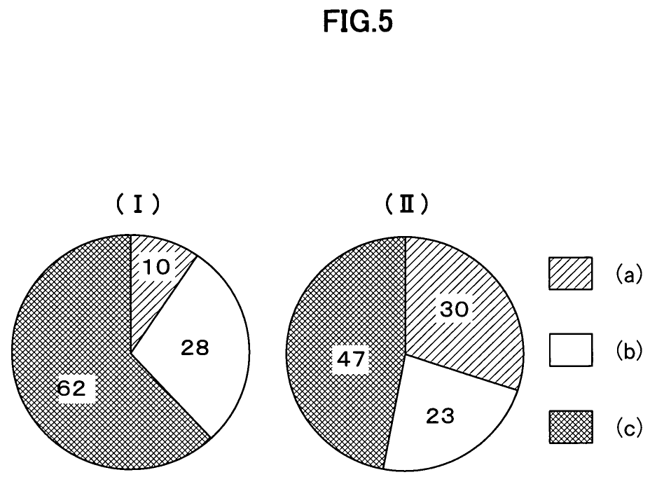

Spherical silicon samples having a particle size of 355 to 600 μm were selected from the entire samples obtained in the Comparative Example and Inventive Example, and respective percentages of three types equivalent to the spherical silicon samples (a) to (c) illustrated in FIG. 4 were evaluated with respect to each of the Comparative Example and Inventive Example. An evaluation result of the Comparative Example is shown in the graph (I) of FIG. 5, and an evaluation result of the Inventive Example is shown in the graph (II) of FIG. 5. Each numeral in circular charts of FIG. 5 indicates a percentage of the three types equivalent to the spherical silicon samples (a) to (c) illustrated in FIG. 4. As seen in the above evaluation results, the present invention makes it possible to obtain a spherical silicon single-crystal having a high degree of crystallinity as in the sample (a) illustrated in FIG. 4, with enhanced efficiency.

As mentioned above, as compared with the conventional techniques, the present invention makes it possible to grow a spherical silicon single-crystal having drastically enhanced crystallinity with significantly higher efficiency at lower cost.

An advantageous embodiment of the present invention has been shown and described. It is obvious to those skilled in the art that various changes and modifications may be made therein without departing from the spirit and scope thereof as set forth in appended claims.

1. A method for producing a spherical silicon single-crystal, comprising the steps of:
heating and melting a silicon material held in a vessel;
keeping the molten silicon material at a temperature around its melting point for a given time-period to partly solidify said molten silicon material; and
dropping the molten silicon material including a solidified portion, from the vessel into a gas phase.

2. The method as defined in claim 1, which further comprises the step of heating said partly-solidified molten silicon material to melt a part of the solidified portion.

3. The method as defined in claim 1, which further comprises the step of stirring said partly-solidified molten silicon material to crush the solidified portion.

4. An apparatus for producing a spherical silicon single-crystal, comprising:
a vessel for holding a silicon material;
heating means for heating and melting the silicon material held in said vessel;
stirring means for stirring the molten silicon material; and
a nozzle for allowing the molten silicon material in said vessel to be dropped into a gas phase,
wherein said apparatus is designed to form a temperature gradient in the molten silicon material in said vessel so as to allow said molten silicon material to be partly solidified.

5. The apparatus as defined in claim 4, wherein:
said vessel includes a crucible having an inner wall at least partly made of boron nitride; and
said stirring means includes a rod made of boron nitride.
